(19) United States
(12) Patent Application Publication
(10) Pub. No.: US 2023/0191945 A1
(43) Pub. Date: Jun. 22, 2023

(54) LEARNING METHOD OF CHARACTERISTIC ESTIMATION MODEL FOR SECONDARY BATTERY, CHARACTERISTIC ESTIMATION METHOD, AND CHARACTERISTIC ESTIMATION DEVICE FOR SECONDARY BATTERY

(71) Applicant: HONDA MOTOR CO., LTD., Tokyo (JP)

(72) Inventor: Minoru Uoshima, Wako-shi (JP)

(21) Appl. No.: 17/989,856

(22) Filed: Nov. 18, 2022

(30) Foreign Application Priority Data
Dec. 21, 2021 (JP) 2021-207074

(51) Int. Cl. B60L 58/16; B60L 58/12; B60L 53/62

(52) U.S. Cl. CPC B60L 58/16; B60L 53/62; B60L 58/12

(57) ABSTRACT

A learning method of a characteristic estimation model for a secondary battery includes: measuring terminal current and terminal voltage of the secondary battery at predetermined time intervals; generating characteristic estimation input data including time series data on the terminal current and the terminal voltage, and time series data on current difference and voltage difference calculated based on the time series data on the terminal current and the terminal voltage; and performing machine learning of a characteristic estimation model using the characteristic estimation input data.

### INCORPORATION BY REFERENCE

The present application claims priority under 35 U.S.C. §119 to Japanese Patent Application No.2021-207074 filed on Dec. 21, 2021. The content of the application is incorporated herein by reference in its entirety.

### BACKGROUND OF THE INVENTION

### Field of the Invention

The present invention relates to a learning method of a characteristic estimation model for estimating internal resistance and open-circuit voltage, which are electric characteristics of a secondary battery in operation, a characteristic estimation method, and a characteristic estimation device for a secondary battery using a learned characteristic estimation model.

### Description of the Related Art

Secondary batteries, which are storage batteries repeatedly usable by recharging, are widely used in moving bodies such as electric vehicles and electric bicycles, and in buildings, or the like. In the case of using these secondary batteries, it is important to appropriately grasp the state of the secondary batteries for the purpose of grasping appropriate timing such as charging timing and replacement timing. Here, the state of the secondary batteries refer to a state of charge (SOC) and a state of health (SOH).

Typically, charge and discharge characteristics of the secondary batteries depend on, for example, electric characteristics, such as internal resistance characteristics and SOC-open circuit voltage (OCV) characteristics of the secondary batteries, and/or the dependency of such electric characteristics on the SOH. Therefore, from the viewpoint of SOC estimation accuracy, it is desirable to use the internal resistance and the OCV of the secondary batteries as an input to a model for estimating the state of the secondary batteries using a neural network, for example. However, as in the case of, for example, an in-vehicle battery connected to a traveling drive motor for a vehicle, it is difficult to accurately measure the internal resistance and the OCV in the secondary batteries where discharge and regeneration (charge) are frequently repeated during traveling.

According to Japanese Patent Laid-Open No. 2003-249271, the internal resistance of a secondary battery in operation is actually measured by inputting an alternating current signal for measurement in between the terminals of the secondary battery. In Japanese Patent Laid-Open No. 2003-249271, the actually measured internal resistance of the secondary battery is used as an input parameter to an SOC estimation model.

In Japanese Patent Laid Open No. 2012-237665, maps are prepared for calculating voltage variation Vir that is attributed to internal resistance Ri corresponding to terminal current and temperature of a secondary battery measured in advance for the secondary battery, and for calculating voltage variation due to polarization of ions in electrolyte. In Japanese Patent Laid Open No. 2012-237665, these maps are referred so as to estimate a present OCV with use of inter-terminal voltage, terminal current, and temperature of the secondary battery in operation.

However, measurement of the internal resistance in Japanese Patent Laid-Open No. 2003-249271 requires an AC signal generator as well as a circuit for measuring amplitude and phase of an AC component appearing in terminal current and terminal voltage, and this leads to cost increase. Moreover, under noisy environments such as in a vehicle engine compartment, it may be difficult to achieve practical measurement accuracy for the internal resistance.

The electric characteristics of secondary batteries may vary depending on the manufacturers and/or types of the secondary batteries. Accordingly, in the configuration where the OCV is estimated using maps of the secondary battery measured in advance as in Japanese Patent Laid Open No. 2012-237665, it is difficult to estimate the OCV with practical accuracy for the secondary battery different in characteristics from the secondary battery measured in advance.

The present invention has been made in light of the above-described circumstances, and an object of the present invention is to accurately estimate the internal resistance and the open-circuit voltage (OCV) of secondary batteries in operation, the secondary batteries being different in manufacturer and type and having various electric characteristics.

The object contributes to improvement of the accuracy of SOC estimation, or the like, of various secondary batteries, and allows efficient operation of the secondary batteries and improvement of battery lives. The object, therefore, can contribute to achievement of sustainable development goals (SDG 7.3, 9.4, 12.2, 12.4, 12.5, etc.).

### SUMMARY OF THE INVENTION

One aspect of the present invention is a learning method of a characteristic estimation model for estimating internal resistance and open-circuit voltage of a secondary battery in operation by machine learning, the secondary battery being connected to a load or a charger. The learning method of a characteristic estimation model for a secondary battery includes: a step of measuring state variables, including terminal current and terminal voltage of the secondary battery in operation, at predetermined time intervals; a step of calculating characteristic estimation input data by preprocessing the state variables; and a step of causing the characteristic estimation model to learn relationship of the characteristic estimation input data with the internal resistance and the open-circuit voltage of the secondary battery in operation by machine learning. In the calculating step, current difference that is difference in the terminal current and voltage difference that is difference in the terminal voltage are calculated based on time series data on the terminal current and time series data on the terminal voltage, and the characteristic estimation input data, including time series data on each of the terminal current, the terminal voltage, the current difference and the voltage difference, is generated.

According to another aspect of the present invention, the current difference is fourth order difference of the time series data on the terminal current, and the voltage difference is fourth order difference of the time series data on the terminal voltage.

According to another aspect of the present invention, the characteristic estimation model is constituted of a recurrent neural network (RNN).

According to another aspect of the present invention, the RNN constituting the characteristic estimation model has an intermediate layer constituted of a long short term memory (LSTM) or a gated recurrent unit (GRU).

According to another aspect of the present invention, the characteristic estimation model is constituted of a first order convolutional neural network (CNN).

According to another aspect of the present invention, the characteristic estimation model is generated by learning using time series data on the state variables, including the terminal current and the terminal voltage of each of the plurality of secondary batteries different in electric characteristics, the secondary batteries being connected to a load or a charger.

Another aspect of the present invention is a characteristic estimation method for a secondary battery. The characteristic estimation method for a secondary battery includes: a step of measuring state variables, including terminal current and terminal voltage of the secondary battery in operation, at predetermined time intervals; a step of calculating characteristic estimation input data by preprocessing the state variables; and a step of estimating internal resistance and open-circuit voltage of the secondary battery in operation based on the characteristic estimation input data, using the characteristic estimation model learned by any one of the learning methods of a characteristic estimation model for a secondary battery. In the calculating step, current difference that is difference in the terminal current and voltage difference that is difference in the terminal voltage are calculated based on time series data on the terminal current and time series data on the terminal voltage, and the characteristic estimation input data, including time series data on each of the terminal current, the terminal voltage, the current difference and the voltage difference, is generated.

Still another aspect of the present invention is a characteristic estimation device for estimating a state of a secondary battery in operation. The characteristic estimation device for a secondary battery includes: a state observation unit configured to measure state variables, including terminal current and terminal voltage of the secondary battery in operation, at predetermined time intervals; a preprocessing unit configured to calculate input data by preprocessing the state variables measured by the state observation unit; and a state estimation unit configured to estimate a present state of charge and/or a present state of health of the secondary battery in operation based on the input data. The state estimation unit estimates a present internal resistance and a present open-circuit voltage of the secondary battery in operation, using the characteristic estimation model learned by any one of the learning methods of a characteristic estimation model for a secondary battery, and the present state of charge and/or the present state of health of the secondary battery in operation is estimated using the estimated internal resistance and open-circuit voltage.

The present invention can accurately estimate the internal resistance and the open-circuit voltage of the secondary batteries in operation, the secondary batteries being different in manufacturer and type and having various electric characteristics.

### BRIEF DESCRIPTION OF THE DRAWINGS

FIG. 1 is a flowchart showing procedures of a learning method for a characteristic estimation model according to a first embodiment of the present invention;

FIG. 2 shows the configuration of a machine learning device that executes the learning method of a characteristic estimation model shown in FIG. 1;

FIG. 3 is a flowchart showing the details of a process in step of calculating characteristic estimation input data in the learning method of a characteristic estimation model shown in FIG. 1;

FIG. 4 is an explanatory view about calculation of current difference in the process shown in FIG. 3;

FIG. 5 is an explanatory view about calculation of voltage difference in the process shown in FIG. 3;

FIG. 6 shows an example of the configuration of a characteristic estimation model generated by a model learning unit of the machine learning device shown in FIG. 2;

FIG. 7 shows an example of estimation of internal resistance and open-circuit voltage of a secondary battery using a learned characteristic estimation model;

FIG. 8 is a flowchart showing procedures of a characteristic estimation method according to a second embodiment of the present invention;

FIG. 9 shows the configuration of a characteristic estimation device that executes the characteristic estimation method shown in FIG. 8; and

FIG. 10 is a functional block diagram of processing devices included in the characteristic estimation device shown in FIG. 9.

### DETAILED DESCRIPTION OF THE PREFERRED EMBODIMENTS

An inventor of the present invention has found out that at least among secondary batteries of the same type (e.g., secondary batteries identical in type called “lithium-ion batteries”), there is correlation between variation aspects of variation in terminal current and terminal voltage of the secondary batteries, i.e. higher order variation aspects, and internal states of the secondary batteries (such as internal resistance, OCV, SOC, and/or SOH). The inventor has obtained a finding that a model (e.g. a neural network), capable of accurately estimating the present state (including present electric characteristics) of the secondary batteries which are different in manufacturer and type and which have various electric characteristics and/or performance, can be generated by using difference (current difference) in time series data on the terminal current and difference (voltage difference) in time series data on the terminal voltage as parameters representing the higher order variation aspects of the terminal current and the terminal voltage of the secondary batteries, and by inputting these differences as input to the model. The present invention is based on such an excellent finding.

Hereinafter, embodiments of the present invention will be described with reference to the drawings.

### First Embodiment

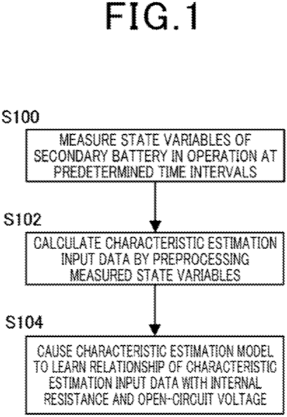

FIG. 1 shows procedures of a learning method of a characteristic estimation model for a secondary battery according to a first embodiment of the present invention. The learning method of a characteristic estimation model includes a step (S100) of measuring state variables, including terminal current and terminal voltage of the secondary battery in operation connected to a load or a charger, at predetermined time intervals, and a step (S102) of calculating characteristic estimation input data by preprocessing the measured state variables. The learning method of a characteristic estimation model also includes a step (S104) of causing the characteristic estimation model to learn relationship of the calculated characteristic estimation input data with the internal resistance and the open-circuit voltage of the secondary battery in operation by machine learning.

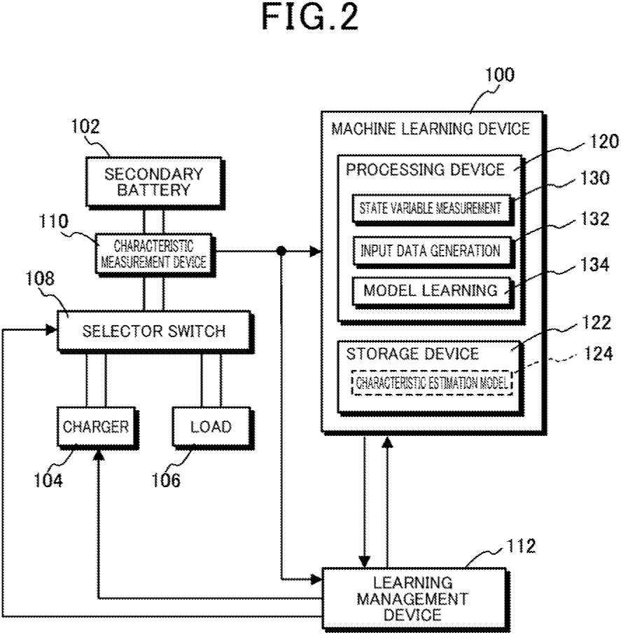

FIG. 2 shows an example of the configuration of a learning management device and a machine learning device that execute the learning method of a characteristic estimation model shown in FIG. 1. The characteristic estimation model is constituted of a neural network, for example. The learning management device 112 controls the operation of a secondary battery 102 during the machine learning. The learning management device 112 also calculates actual measurement values of the internal resistance and the open-circuit voltage as teacher data, and provides the calculated values to a machine learning device 100.

The secondary battery 102 is charged by a charger 104 and discharged by energization of a load 106. The charger 104 is a direct-current power source, for example, and the load 106 is a motor, for example. Charging the secondary battery 102 from the charger 104 or discharging the secondary battery 102 to the load 106 is selected by a selector switch 108. Between the selector switch 108 and the secondary battery 102, a characteristic measurement device 110 is interposed

The characteristic measurement device 110 measures present values of predetermined state variables of the secondary battery 102. The predetermined state variables may include a terminal voltage Vte, a terminal current Ite, an internal resistance Ri of the secondary battery 102, and a surface temperature T (°C) of a housing of the secondary battery 102. Here, the internal resistance Ri can be measured by inputting, for example, alternating current that is a measurement signal to the secondary battery 102 in accordance with conventional technologies.

The terminal current Ite of the secondary battery 102 takes a positive value when the secondary battery 102 is discharged, and takes a negative value when the secondary battery 102 is charged.

### 1. Learning Management Device

The learning management device 112 controls charge and discharge of the secondary battery 102. The learning management device 112 also generates teacher data for learning of a characteristic estimation model and outputs the teacher data to the machine learning device 100. The learning management device 112 is, for example, a computer that initiates operation by an instruction from an operator. The learning management device 112 instructs the charger 104 to start and stop power output, and instructs the selector switch 108 to perform switching operation.

The learning management device 112 acquire from the characteristic measurement device 110 the terminal current Ite, the terminal voltage Vte and the internal resistance Ri of the secondary battery 102 during charging and discharging, at predetermined time intervals.

The learning management device 112 calculates an open-circuit voltage Voc of the secondary battery 102 from the acquired terminal current Ite, terminal voltage Vte, and internal resistance Ri, and generates time series data on each of the internal resistance Ri and the open-circuit voltage Voc. The time series data on the internal resistance Ri and the open-circuit voltage Voc are used as teacher data for learning of the characteristic estimation model executed by the machine learning device 100 described later.

### 2. Machine Learning Device

The machine learning device 100 executes a learning method of a characteristic estimation model shown in FIG. 1. The machine learning device 100 includes a processing device 120, and a storage device 122. The storage device 122 is constituted of, for example, a volatile and/or non-volatile semiconductor memory, and/or a hard disk device, or the like. The storage device 122 stores a characteristic estimation model 124 generated by a model learning unit 134 described later.

The processing device 120 is a computer including a processor such as a central processing unit (CPU), for example. The processing device 120 may be configured to include a read-only memory (ROM) having programs written therein, a random-access memory (RAM) for temporary data storage, and so on. The processing device 120 includes, as a functional element or a function unit, a state variable measurement unit 130, an input data generation unit 132, and the model learning unit 134.

These functional elements included in the processing device 120 are implemented when the processing device 120 that is a computer executes programs. Note that the computer programs can be stored in any computer-readable storage medium. Alternatively, all or some of the functional elements included in the processing device 120 may each be constituted of hardware including one or more electronic circuit components.

### 2.1 Function of State Variable Measurement Unit

The state variable measurement unit 130 executes step S100 shown in FIG. 1. Specifically, the state variable measurement unit 130 acquires from the characteristic measurement device 110 the state variables, including the terminal current Ite and the terminal voltage Vte of the secondary battery 102 connected to the load 106 or the charger 104, at predetermined time intervals. This causes the state variable measurement unit 130 to measure the state variables at predetermined time intervals. The state variable measurement unit 130 may further measure temperature T of the secondary battery 102 as a state variable at predetermined time intervals.

### 2.2 Function of Input Data Generation Unit

The input data generation unit 132 executes step S102 shown in FIG. 1. Specifically, the input data generation unit 132 calculates characteristic estimation input data by preprocessing the state variables measured by the state variable measurement unit 130.

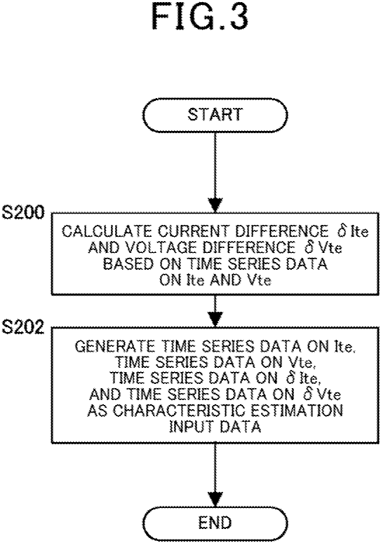

FIG. 3 is a flowchart showing the details of the process in step 102 of calculating the characteristic estimation input data shown in FIG. 1. In step S102 of calculating the characteristic estimation input data, the input data generation unit 132 calculates current difference δIte that is difference in the terminal current Ite and voltage difference δVte that is difference in the terminal voltage Vte, based on time series data on the terminal current Ite and time series data on the terminal voltage Vte (S200). The input data generation unit 132 then generates state estimation input data including following four time series data sets during a period from the past that goes back by a predetermined time T1 from the present to the present (S202), and ends the process:
time series data on terminal current Ite;
time series data on terminal voltage Vte;
time series data on current difference δIte; and
time series data on voltage difference δVte.

Hereinafter, specific calculation methods of the current difference δIte and the voltage difference δVte will be described.

### 2.2.2.1. Calculation of Current Difference δIte

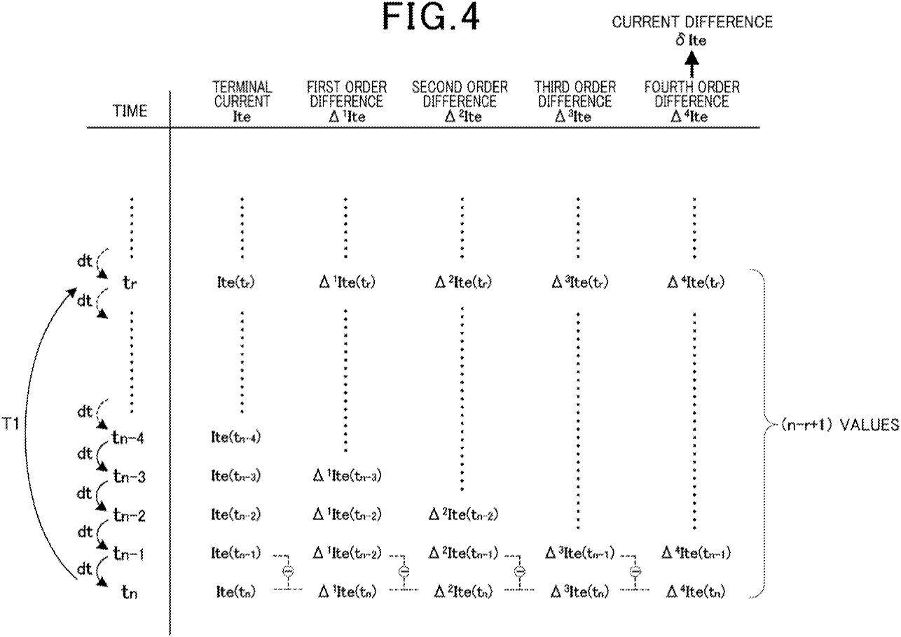

FIG. 4 is an explanatory view about calculation of the current difference δIte. In a table shown in FIG. 4, a left-most column is a first column, followed by a second column, a third column, ... a sixth column to the right. The first column of the table in FIG. 4 indicates the time at which the state variable measurement unit 130 repeatedly acquires the terminal current Ite at predetermined time intervals dt, or the index (number) of the time. The second column is the time series data on the terminal current Ite, which indicates the terminal current Ite acquired at each time.

The third column, the fourth column, the fifth column, and the sixth column respectively indicate a first order difference Δ¹Ite, a second order difference Δ²Ite, a third order difference Δ³Ite, and a fourth order difference Δ⁴Ite of the terminal current Ite, which are calculated from the terminal current Ite in the second row.

An h-th order difference Δ^{h}Ite (tₙ) (h = 1, 2, ... 4) at present time tₙ is calculated by a following expression:

$${Δ}^{\text{h}} \text{Ite} \left({\text{t}}_{\text{n}}\right) = {Δ}^{\text{h-1}} \text{Ite} \left({\text{t}}_{\text{n}}\right) - {Δ}^{\text{h-1}} \text{Ite} \left({\text{t}}_{\text{n-1}}\right)$$

where h = 1, 2, 3, 4, and also Δ⁰Ite (tₙ) = Ite (tₙ)

Specifically, the first order difference Δ¹Ite (tₙ) at time tₙ is calculated by subtracting the terminal current Ite (tₙ₋₁) at time tₙ₋₁ from the terminal current Ite (tₙ) at time tₙ. The second order difference Δ²Ite (tₙ) at time tₙ is calculated by subtracting the first order difference Δ¹Ite (tₙ₋₁) at time tₙ₋₁ from the first order difference Δ¹Ite (tₙ) at time tₙ.

Similarly, the third order difference A³Ite (tₙ) at time tₙ is calculated by subtracting the second order difference Δ²Ite (tₙ₋₁) at time tₙ₋₁ from the second order difference Δ²Ite (tₙ) at time tₙ. The fourth order difference Δ⁴Ite (tₙ) at time tₙ is calculated by subtracting the third order difference Δ³Ite (tₙ₋₁) at time tₙ₋₁ from the third order difference Δ³Ite (tₙ) at time tₙ.

In the present embodiment, the input data generation unit 132 defines the fourth order difference Δ⁴Ite of the terminal current Ite at each time as the current difference δIte. This means as follows:

$$\text{δ} \text{Ite} \left(\text{t}\right) = {\text{Δ}}^{4} \text{Ite} \left(\text{t}\right) , \text{t} = {\text{t}}_{\text{n}} , {\text{t}}_{\text{n} - 1} , …$$

### 2.2.2.2. Calculation of Voltage Difference δVte

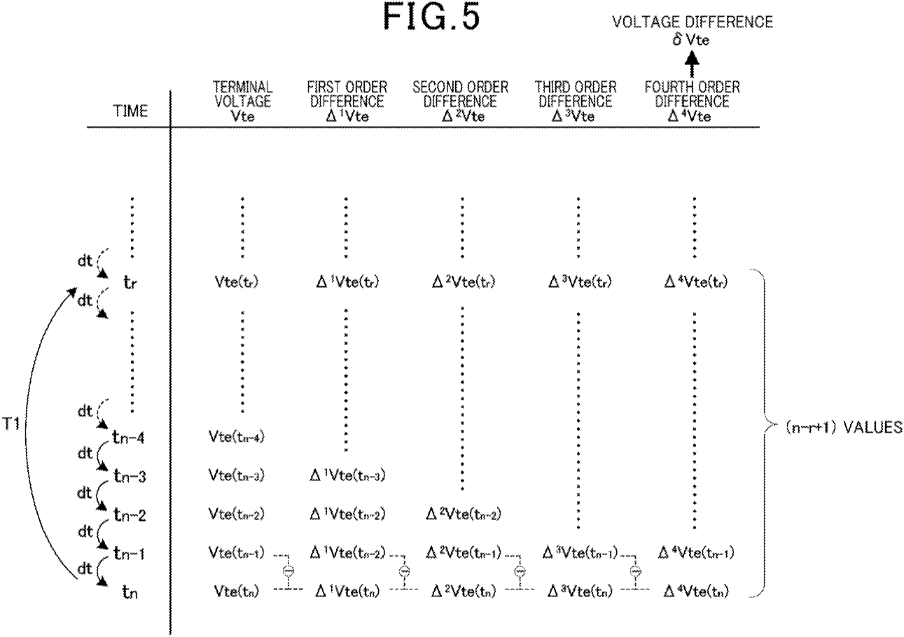

The input data generation unit 132 calculates the voltage difference δVte of the terminal voltage Vte, as in the case of the current difference described before. FIG. 5 shows the procedures for calculation of the voltage difference δVte. In a table shown in FIG. 5, a left-most column is a first column, followed by a second column, a third column, ... a sixth column to the right. The first column of the table in FIG. 5 indicates the time at which the state variable measurement unit 130 repeatedly acquires the terminal voltage Vte at predetermined time intervals dt, or the index (number) of the time. The second column is the time series data on the terminal voltage Vte, which indicates the terminal voltage Vte acquired at each time.

The third column, the fourth column, the fifth column, and the sixth column respectively indicate a first order difference Δ¹Vte, a second order difference Δ²Vte, a third order difference Δ³Vte, and a fourth order difference Δ⁴Vte of the terminal voltage Vte, which are calculated from the terminal voltage Vte in the second row.

An h-th order difference Δ^{h}Vte (tₙ) (h = 1, 2, ... 4) at present time tₙ is calculated by a following expression:

$${Δ}^{\text{h}} \text{Vte} \left({\text{t}}_{\text{n}}\right) = {Δ}^{\text{h-1}} \text{Vte} \left({\text{t}}_{\text{n}}\right) - {Δ}^{\text{h-1}} \text{Vte} \left({\text{t}}_{\text{n-1}}\right)$$

where h = 1, 2, 3, 4, and also

$${Δ}^{0} \text{Vte} \left({\text{t}}_{\text{n}}\right) = \text{Vte} \left({\text{t}}_{\text{n}}\right)$$

Specifically, the first order difference Δ¹Vte (tₙ) at time tₙ is calculated by subtracting the terminal voltage Vte (tₙ₋₁) at time tₙ₋₁ from the terminal voltage Vte (tₙ) at time tₙ. The second order difference Δ²Vte (tₙ) at time tₙ is calculated by subtracting the first order difference Δ¹Vte (tₙ₋₁) at time tₙ₋₁ from the first order difference Δ⁴Vte (tₙ) at time tₙ.

Similarly, the third order difference Δ³Vte (tₙ) at time tₙ is calculated by subtracting the second order difference Δ²Vte (tₙ₋₁) at time tₙ₋₁ from the second order difference Δ²Vte (tₙ) at time tₙ. The fourth order difference Δ⁴Vte (tₙ) at time tₙ is calculated by subtracting the third order difference Δ³Vte (tₙ₋₁) at time tₙ₋₁ from the third order difference Δ³Vte (tₙ) at time tₙ.

In the present embodiment, the input data generation unit 132 defines the fourth order difference Δ⁴Vte of the terminal voltage Vte at each time as the voltage difference δVte. This means as follows:

$$\text{δ} \text{Vte} \left(\text{t}\right) = {\text{Δ}}^{4} \text{Vte} \left(\text{t}\right) , \text{t} = {\text{t}}_{\text{n}} , {\text{t}}_{\text{n} - 1} , …$$

### 2.2.2.3 Characteristic Estimation Input Data

As described above, the characteristic estimation input data is constituted of time series data on each of the terminal current Ite, the terminal voltage Vte, the current difference δIte, and the voltage difference δVte during a period from the past that goes back by predetermined time T1 from the present to the present. When the present time is tₙ, and the time in the past that goes back by predetermined time T1 from the present is tr, then the characteristic estimation input data is expressed by a following expression:

$$\begin{matrix}{}_{}^{v}{x} l \left({t}_{n}\right) = \left(\begin{matrix}{}_{}^{v}{l} t e \left({t}_{n}\right) \\ {}_{}^{v}{V} t e \left({t}_{n}\right) \\ {}_{}^{v}{δ} l t e \left({t}_{n}\right) \\ {}_{}^{v}{δ} V l t e \left({t}_{n}\right)\end{matrix}\right) \\ \text{where} \\ {}_{}^{v}{l} t e \left({t}_{n}\right) = \left(l t e \left({t}_{r}\right) , l t e \left({t}_{r + 1}\right) , l t e \left({t}_{r + 2}\right) , … , l t e \left({t}_{n}\right)\right) \\ {}_{}^{v}{V} t e \left({t}_{n}\right) = \left(V t e \left({t}_{r}\right) , V t e \left({t}_{r + 1}\right) , V t e \left({t}_{r + 2}\right) , … , V t e \left({t}_{n}\right)\right) \\ {}_{}^{v}{δ} l t e \left({t}_{n}\right) = \left(δ l t e \left({t}_{r}\right) , δ l t e \left({t}_{r + 1}\right) , δ l t e \left({t}_{r + 2}\right) , … , δ l t e \left({t}_{n}\right)\right) \\ {}_{}^{v}{δ} V l t e \left({t}_{n}\right) = \left(δ V l t e \left({t}_{r}\right) , δ V l t e \left({t}_{r + 1}\right) , δ V l t e \left({t}_{r + 2}\right) , … , δ V l t e \left({t}_{n}\right)\right) .\end{matrix}$$

Here, time series data ^{v}Ite (tₙ) on the terminal current Ite, time series data ^{v}Vte (tₙ) on the terminal voltage Vte, time series data ^{v}δIte (tₙ) on the current difference, and time series data ^{v}δVte (tₙ) on the voltage difference are first order tensors having elements of n-r+1 values, corresponding respectively to the terminal current Ite, the terminal voltage Vte, the current difference δIte, and the voltage difference δVte from time tᵣ to time tₙ. Therefore, a characteristic estimation input data ^{v}x1 (tₙ) is a second order tensor.

### 2.3 Functions of Model Learning Unit

The model learning unit 134 executes step S104 in the learning method of a characteristic estimation model shown in FIG. 1 to generate the characteristic estimation model 124 by machine learning. Specifically, the model learning unit 134 uses the characteristic estimation input data generated by the input data generation unit 132 to cause the characteristic estimation model 124 to learn by machine learning. In the learning, the model learning unit 134 acquires, for example, the time series data on the internal resistance Ri and the time series data on the open-circuit voltage Voc of the secondary battery 102 from the learning management device 112. The model learning unit 134 uses the acquired time series data on each of the internal resistance Ri and the open-circuit voltage Voc as teacher data to perform the machine learning.

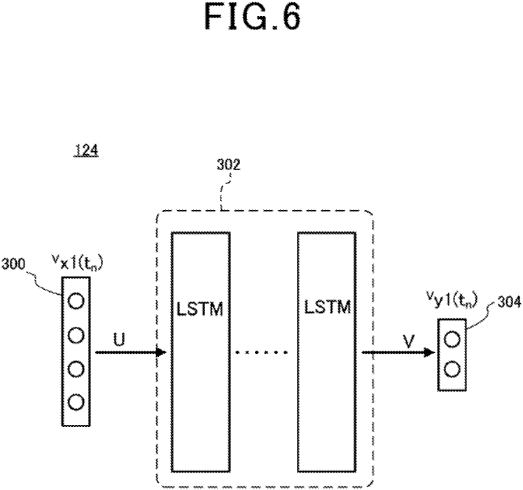

FIG. 6 shows the configuration of the characteristic estimation model 124 generated by the model learning unit 134. The characteristic estimation model 124 is constituted of a neural network including an input layer 300, an intermediate layer 302, and an output layer 304. The characteristic estimation model 124 is, for example, a recurrent neural network (RNN).

The input layer 300 receives the characteristic estimation input data of a second order tensor shown in the expression (1) described above. The intermediate layer 302 includes a multi-layered long short term memory (LSTM) in the present embodiment. However, the intermediate layer 302 is not limited to the LSTM. For example, the intermediate layer 302 may be constituted of a gated recurrent unit (GRU).

The output layer 304 outputs estimated values of the internal resistance Ri and the open-circuit voltage Voc of the secondary battery 102 at time tₙ as an output ^{v}y1 (tₙ) . Specifically, the output ^{v}y1 (tₙ) is a vector having the internal resistance Ri (tₙ) and the open-circuit voltage Voc (tₙ), which are scalar quantities, as elements.

### 3. Secondary Batteries Used in Model Learning

As the secondary battery 102 used in model learning, a variety of secondary batteries which are different in manufacturer and type and different in electric characteristics are desirably used. This makes it possible to generate the characteristic estimation model 124 having estimation accuracy less varied by manufacturers and types. For example, when learning of the characteristic estimation model 124 is performed, it is desirable to use a plurality of secondary batteries different in electric characteristics, such as SOC-OCV characteristics, SOC-internal resistance characteristics, and/or SOH dependency thereof.

### 4. Operational Aspect of Secondary Batteries in Model Learning

An operational aspect (charge and discharge story) of secondary batteries in model learning may desirably include random execution of charge and discharge and/or alternate execution of charge and discharge in accordance with predetermined standards, in addition to monotonous discharge or charge between a fully charged state (SOC = 100%) and a fully discharged state (SOC = 0%). Such predetermined standards may be based on use cases for various uses of the secondary batteries to be estimated. For example, when secondary batteries for a vehicle are assumed to be estimated, it is possible to use the standards which are tailored to typical charge and discharge cycles in vehicle traveling in various traffic situations, such as urban areas, mountain areas, rural areas, and highways.

### 5. Learning Data Collection

In the present embodiment, the time series data on each of the state variables (Ite and Vte) of the secondary battery 102, which are the source of learning data for the characteristic estimation model 124, and the time series data on the internal resistance Ri and the open-circuit voltage Voc, which are teacher data, are acquired from the characteristic measurement device 110 by the machine learning device 100, and are calculated by the learning management device 112, and these data are immediately used for learning of the characteristic estimation model 124. However, the time series on the state variables and the time series on the teacher data are not necessarily used immediately for learning.

The learning management device 112 may acquire and store the time series on the state variables and the time series on the teacher data in advance by activating the secondary batteries. The machine learning device 100 may acquire the time series data on the state variables and the time series on the teacher data stored by the learning management device 112 from the learning management device 112, and perform machine learning for the characteristic estimation model 124.

Unless error between simulated data and actual data poses practical problem, the time series on the state variables and the time series on the teacher data may be generated by simulating the charge and discharge characteristics, which are grasped from design materials of an equivalent circuit of the secondary battery 102 and the like, on a computer.

### 6. Examples of Internal Resistance Estimation and Open-Circuit Voltage Estimation by Characteristic Estimation Model

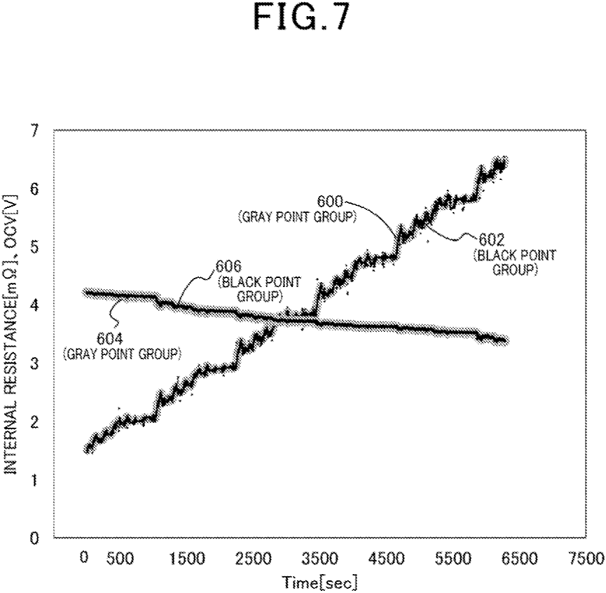

Description is now given of examples of internal resistance estimation and open-circuit voltage estimation for the secondary battery using the characteristic estimation model learned based on the learning method according to the present embodiment. FIG. 7 shows examples of the internal resistance estimation and the open-circuit voltage estimation for the secondary battery using the learned characteristic estimation model.

Learning data for the characteristic estimation model was generated by simulating the charge and discharge characteristics of dozens of types of sample secondary batteries for a vehicle, which are different in electric characteristics. Specifically, the terminal current Ite, the terminal voltage Vte, the internal resistance, and the open-circuit voltage at predetermined time intervals dt, in the case where each of the dozens of sample secondary batteries different in the SOC-OCV characteristics, internal resistance characteristics, and capacity characteristics (SOH) as electric characteristics are charged and discharged in accordance with a predetermined charge and discharge story, were calculated by simulation on the computer.

The charge and discharge story was tailored to typical charge and discharge cycles in vehicle traveling in various traffic situations, such as urban areas, mountain areas, rural areas, and highways, in addition to simply allowing monotonous discharge or charge of the sample secondary batteries between a fully charged state (SOC = 100%) and a fully discharged state (SOC = 0%).

The sample secondary batteries are lithium-ion batteries. A measurement time intervals dt of the state variables is 100 ms, and the predetermined time T1 for calculating the characteristic estimation input data for the characteristic estimation model described above is 5 seconds. Note that these time values are merely exemplary, and the measurement time intervals dt and the predetermined time T1 may be set to time values different from the exemplary values.

FIG. 7 shows the results of estimating the internal resistance and the open-circuit voltage of one secondary battery by the learned characteristic estimation model, and simulated values of the internal resistance and the open-circuit voltage, during a period in which the target secondary battery is discharged from a fully charged state to a fully discharged state. The one secondary battery is randomly selected as estimation target (hereinafter a target secondary battery) from the sample secondary batteries.

In FIG. 7, a horizontal axis represents time elapsed since the start of discharge when the secondary battery starts to be discharged from the fully charged state, and a vertical axis represents the internal resistance (unit: mΩ) and the open-circuit voltage (OCV) (unit: V) of the target secondary battery. The characteristic estimation input data given to the characteristic estimation model in characteristic estimation (i.e. estimation of the internal resistance and the open-circuit voltage) were calculated based on values Ite and Vte at every predetermined time interval dt during discharge of the target secondary battery, the values Ite and Vte being calculated by simulation based on the charge and discharge characteristics of the target secondary battery.

In FIG. 7, a line 600, formed by a set of gray points and illustrated to be upward to the right, indicates internal resistance values calculated by simulation based on the charge and discharge characteristics of the target secondary battery. On the other hand, a line 602, formed by a set of black points, indicates internal resistance estimation values estimated by the characteristic estimation model.

In FIG. 7, a line 604, formed by a set of gray points and illustrated to be downward to the right, indicates open-circuit voltage values calculated by simulation based on the charge and discharge characteristics of the target secondary battery. On the other hand, a line 606, formed by a set of black points, indicates open-circuit voltage estimation values estimated by the characteristic estimation model.

Comparison between the line 600 and the line 602, and comparison between the line 604 and the line 606 shown in FIG. 7 indicate that the internal resistance and the open-circuit voltage of the target secondary battery have been accurately estimated by the characteristic estimation model learned by the learning method shown in the present embodiment. Although the characteristic estimation model used for the estimation has been generated by using learning data on dozens of sample secondary batteries different in electric characteristics in particular, the internal resistance estimation values and the open-circuit voltage estimation values obtained from the characteristic estimation model each have converged to one line (lines 602 and 604) without diverging, and the internal resistance and the open-circuit voltage of a specific target secondary battery have been accurately estimated. Accordingly, since the learning method according to the present embodiment uses a plurality of secondary batteries different in electric characteristics, the characteristic estimation model learned by the learning method can accurately estimate the internal resistance and the open-circuit voltage of a wide variety of secondary batteries in operation which are different in manufacturer and type.

### Second Embodiment

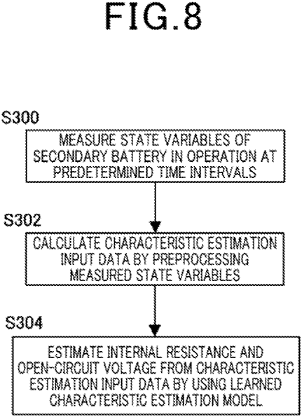

Description is now given of a second embodiment of the present invention. FIG. 8 shows procedures of a characteristic estimation method for a secondary battery according to the second embodiment of the present invention. The characteristic estimation method includes a step (S300) of measuring state variables, including terminal current and terminal voltage of the secondary battery in operation connected to a load or a charger, at predetermined time intervals, and a step (S302) of calculating characteristic estimation input data by preprocessing the measured state variables. The characteristic estimation method also includes a step (S304) of estimating the internal resistance and the open-circuit voltage of the secondary battery in operation based on the characteristic estimation input data, by using a characteristic estimation model learned by the learning method according to the first embodiment described before.

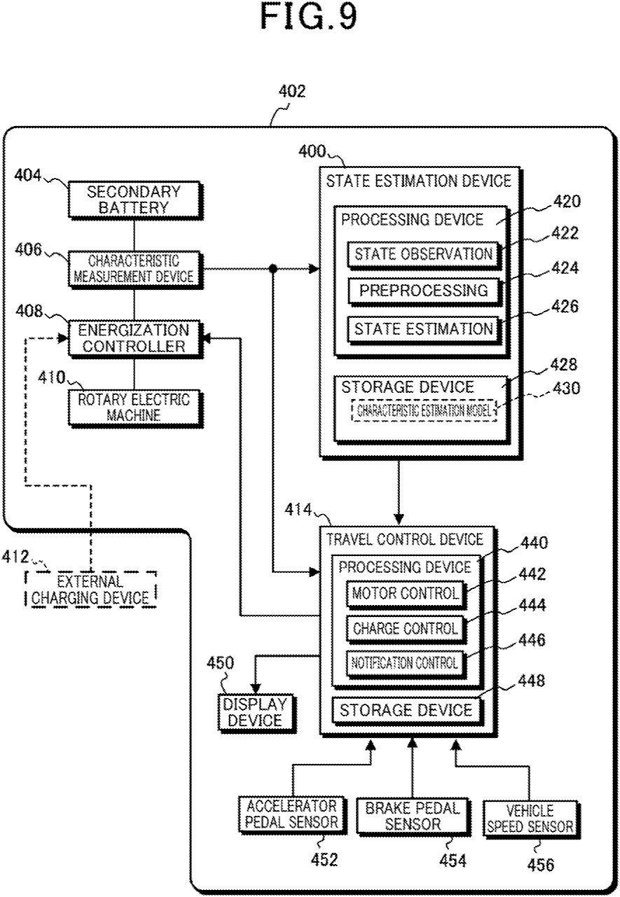

The characteristic estimation method shown in FIG. 8 is executed in a characteristic estimation device 400 shown in FIG. 9, for example. The characteristic estimation device 400 is mounted on, for example, a vehicle 402 that is an electric vehicle, and estimates the state of a secondary battery 404 in operation as an in-vehicle battery of the vehicle 402. The secondary battery 404 is connected to a rotary electric machine 410 via a characteristic measurement device 406 and an energization controller 408.

The rotary electric machine 410 functions as a motor that is powered by discharging from the secondary battery 404 and drives the wheels of the vehicle 402, and also functions as a power generator that generates electric power by rotative force transmitted from the wheels and charges the secondary battery 404.

The characteristic measurement device 406 measures present values of the state variables, including the terminal current Ite and the terminal voltage Vte of the secondary battery 404. The energization controller 408 controls a charge amount from the secondary battery 404 to the rotary electric machine 410 and an energization amount from the rotary electric machine 410 to the secondary battery 404 under the control of a travel control device 414 mounted on the vehicle 402. The energization controller 408 controls the energization amount from an external charging device 412 to the secondary battery 404 under the control of the travel control device 414, when the external charging device 412 outside the vehicle 402 is connected to the vehicle 402. The external charging device 412 is, for example, a charger in a charging stand. The energization controller 408 can also control the energization amount from the power generator to the secondary battery when another power generator driven by an internal combustion engine is mounted on the vehicle 402.

The travel control device 414 acquires from the characteristic estimation device 400 present SOC and SOH estimation values indicating the state of the secondary battery 404, controls the operation of the rotary electric machine 410 based on the acquired SOC and SOH, and performs user notification.

Specifically, the travel control device 414 includes a processing device 440 and a storage device 448. The storage device 448 is a semiconductor memory, for example, which stores data needed for processing in the processing device 440.

The processing device 440 is a computer including a processor such as a CPU, for example. The processing device 440 may be configured to include a ROM having programs written therein, a RAM for temporary data storage, and so on. The processing device 440 includes, as a functional element or a function unit, a motor control unit 442, a charge control unit 444, and a notification control unit 446.

These functional elements included in the processing device 440 are implemented when the processing device 440 that is a computer executes programs. Note that the computer programs can be stored in any computer-readable storage medium. Alternatively, all or some of the functional elements included in the processing device 440 may each be constituted of hardware including one or more electronic components.

The motor control unit 442 detects a pressing amount of an accelerator pedal (not shown) of the vehicle 402 through an accelerator pedal sensor 452. When the accelerator pedal is pressed, the travel control device 414 instructs the energization controller 408 to energize the rotary electric machine 410 from the secondary battery 404 and operates the rotary electric machine 410 as a motor to make the vehicle 402 travel. The travel control device 414 also controls the number of rotation of the rotary electric machine 410 via the energization controller 408 such that the speed of the vehicle 402 acquired from a vehicle speed sensor 456 coincides with the speed corresponding to the pressing amount of the accelerator pedal.

At the time, the motor control unit 442 limits an upper limit of current (maximum energization current) supplied from the secondary battery 404 to the rotary electric machine 410 when, for example, the vehicle 402 accelerates or travels at a constant speed, based on the present SOC estimation value acquired from the characteristic estimation device 400. Specifically, in order to, for example, limit the discharge of the secondary battery 404 by limiting the torque generated by the rotary electric machine 410, the motor control unit 442 determines the maximum energization current so that fuel efficiency (e.g. a travel distance per kWh), determined based on the characteristics of the secondary battery 404 and the rotary electric machine 410, is a predetermined value or more.

The charge control unit 444 determines whether or not a brake pedal (not shown) of the vehicle 402 is pressed through a brake pedal sensor 454. When the brake pedal is pressed, the charge control unit 444 instructs the motor control unit 442 to stop energization of the rotary electric machine 410 from the secondary battery 404. Then, the charge control unit 444 instructs the energization controller 408 to energize the secondary battery 404 by the rotary electric machine 410, operates the rotary electric machine 410 as a power generator, and causes the rotary electric machine 410 to charge the secondary battery 404 (so-called regenerative braking operation).

The charge control unit 444 controls a power feed amount from the external charging device 412 to the secondary battery 404 via the energization controller 408, when the vehicle 402 is connected to the external charging device 412.

The notification control unit 446 provides a designated display on a display device 450, based on the present SOC and SOH estimation values acquired from the characteristic estimation device 400. For example, the notification control unit 446 simply displays the acquired present SOC and SOH estimation values on the display device 450. For example, the notification control unit 446 also displays on the display device 450 a message of suggesting charging at a charge stand to a driver of the vehicle 402, when the SOC estimation value falls below a predetermined value. Alternatively, the notification control unit 446 also displays on the display device 450 a message of suggesting replacement of the secondary battery 404 to the driver of the vehicle 402, when the SOH estimation value falls below the predetermined value, for example.

The characteristic estimation device 400 executes the characteristic estimation method shown in FIG. 8 to estimate the internal resistance and the open-circuit voltage of the secondary battery 404 in operation. Then, the characteristic estimation device 400 estimates the SOC and the SOH of the secondary battery 404 based on the estimated internal resistance and open-circuit voltage, and outputs the present SOC estimation value and SOH estimation value to the travel control device 414.

Specifically, the characteristic estimation device 400 includes a processing device 420 and a storage device 428. The storage device 428 is constituted of nonvolatile and volatile semiconductor memories. The storage device 428 stores the characteristic estimation model 124 learned by the learning method according to the first embodiment in advance as a characteristic estimation model 430.

The processing device 420 is a computer including a processor such as a CPU, for example. The processing device 420 may be configured to include a ROM having programs written therein, a RAM for temporary data storage, and so on. The processing device 420 includes, as a functional element or a function unit, a state observation unit 422, a preprocessing unit 424, and a state estimation unit 426.

These functional elements included in the processing device 420 are implemented when the processing device 420 that is a computer executes programs. Note that the computer programs can be stored in any computer-readable storage medium. Alternatively, all or some of the functional elements included in the processing device 420 may each be constituted of hardware including one or more electronic components.

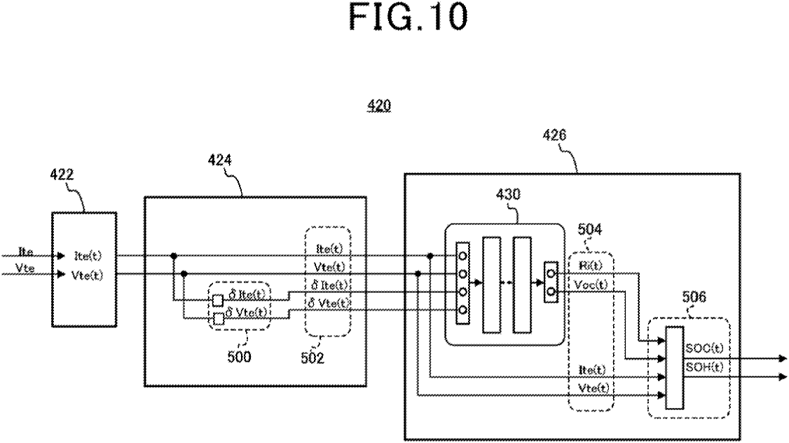

A functional block diagram of the processing device 420, including the state observation unit 422, the preprocessing unit 424, and the state estimation unit 426, is shown in FIG. 10. In FIG. 10, dotted-line rectangles indicate processes in the preprocessing unit 424 and the state estimation unit 426, respectively.

The state observation unit 422 executes step S300 in the characteristic estimation method shown in FIG. 8. Specifically, the state observation unit 422 acquires from the characteristic measurement device 406 the state variables of the secondary battery 404, including the terminal current Ite(t) and the terminal voltage Vte(t) of the secondary battery 404 in operation, at predetermined time intervals. This allows the state observation unit 422 to obtain time series data on the state variables measured at the predetermined time intervals.

The preprocessing unit 424 executes step S302 in the characteristic estimation method shown in FIG. 8. Specifically, the preprocessing unit 424 calculates characteristic estimation input data by preprocessing the state variables acquired by the state observation unit 422. Specifically, the preprocessing unit 424 calculates current difference δIte that is difference in the terminal current Ite and voltage difference δVte that is difference in the terminal voltage Vte, based on time series data on the terminal current Ite and time series data on the terminal voltage Vte acquired by the state observation unit 422 (a process 500 shown in FIG. 10).

The preprocessing unit 424 then generates the characteristic estimation input data including the time series data on each of the terminal current Ite, the terminal voltage Vte, the current difference δIte and the voltage difference δVte during a period from the past that goes back by predetermined time T1 from the present time to the present time (a process 502 in FIG. 10).

The state estimation unit 426 then executes step S304 in the characteristic estimation method shown in FIG. 8. Specifically, the state estimation unit 426 uses the learned characteristic estimation model to estimate the internal resistance Ri and the open-circuit voltage Voc of the secondary battery 404 in operation, based on the generated characteristic estimation input data (a process 504 in FIG. 10).

Then, with use of, for example, the time series data on each of the internal resistance Ri, the open-circuit voltage Voc, the terminal voltage Vte, and the terminal current Ite from the past that goes back by predetermined time T2 from the present time to the present time as an input, the state estimation unit 426 estimates the SOC and the SOH as the present state of the secondary battery 404 using, for example, a state estimation mode learned by machine learning (a process 506 in FIG. 10).

### Other Embodiments

Without being limited to the embodiments disclosed, the present invention can be carried out in various aspects without departing from the spirit thereof.

In the first and second embodiments, the current difference δIte and the voltage difference δVte are assumed to be the fourth order difference Δ⁴Ite of the terminal current and the fourth order difference Δ⁴Vte of the terminal voltage, respectively. However, the current difference δIte and the voltage difference δVte are not necessarily the fourth order differences. The current difference δIte and the voltage difference δVte may be, for example, a first order difference Δ¹Ite and a first order difference Δ¹Vte, respectively. However, the fourth or higher order differences are preferable from the viewpoint of more accurate estimation of the open-circuit voltage of the secondary batteries which are different in manufacturer and type, since the fourth or higher order differences make it possible to extract more common variation aspects of terminal current and terminal voltage in the secondary batteries different in electric characteristics.

Moreover, time series data on temperature of the secondary battery 102 may be added to the characteristic estimation input data. This can further enhance the estimation accuracy of the internal resistance and the open-circuit voltage by the characteristic estimation model 124. In the case where the secondary batteries are lithium-ion batteries in particular, the temperature dependency of the internal resistance is relatively high. Therefore, including the temperature of the secondary batteries in the characteristic estimation input data is desirable from the viewpoint of accurately measuring the internal resistance and the open-circuit voltage of the wide variety of secondary batteries 102 having various electric characteristics.

In the embodiments disclosed, the characteristic estimation model 124 is the RNN that makes it easy to handle chronologically continuous data as an input. However, the configuration of the characteristic estimation model is not limited to the RNN.

For example, the characteristic estimation model 124 may be configured with a first order convolutional neural network (CNN). In this case, the characteristic estimation input data expressed as a second order tensor (expression (1)) can also be used as an input into the characteristic estimation model 124.

In the second embodiment disclosed, the characteristic estimation device 400 that estimates the state of the secondary battery 404 in operation mounted on the vehicle 402 is shown as an example of the device that executes step S304 of estimating the internal resistance and the open-circuit voltage of the secondary battery in operation. However, it is also possible to use step S304 of estimating the internal resistance and the open-circuit voltage of the secondary battery in operation for estimating the state of the secondary batteries for any uses, such as secondary batteries for mobile phones, secondary batteries for bicycles, and secondary batteries for household use, in addition to the secondary batteries for vehicles.

In the second embodiment disclosed, the characteristic estimation method shown in FIG. 8 is performed in the characteristic estimation device 400 that estimates the state of the secondary battery. However, this is merely an example, and the characteristic estimation method may be executed in a single device that only performs estimation of the internal resistance and the open-circuit voltage. Alternatively, the characteristic estimation method may be executed in another device having various functions. For example, the characteristic estimation method shown in FIG. 8 can be executed in a controller that controls the load of the secondary battery. As a specific example, the state observation unit 422, the preprocessing unit 424, and the state estimation unit 426 included in the processing device 420 in the characteristic estimation device 400 in FIG. 9 may be implemented in the processing device 440 of the travel control device 414, for example. In this case, the characteristic estimation model 430 stored in the storage device 428 is stored in the storage device 448 of the travel control device 414.

### Configurations Supported by Embodiments

The embodiments disclosed support the following configurations.

(Configuration 1) A learning method of a characteristic estimation model for estimating internal resistance and open-circuit voltage of a secondary battery in operation by machine learning, the secondary battery being connected to a load or a charger, the method including: a step of measuring state variables, including terminal current and terminal voltage of the secondary battery in operation, at predetermined time intervals; a step of calculating characteristic estimation input data by preprocessing the state variables; and a step of causing the characteristic estimation model to learn relationship of the characteristic estimation input data with the internal resistance and the open-circuit voltage of the secondary battery in operation by machine learning, wherein in the calculating step, current difference that is difference in the terminal current and voltage difference that is difference in the terminal voltage are calculated based on time series data on the terminal current and time series data on the terminal voltage, and the characteristic estimation input data, including time series data on each of the terminal current, the terminal voltage, the current difference and the voltage difference, is generated.

According to the learning method of a characteristic estimation model in the configuration 1, the generated characteristic estimation model makes it possible to accurately estimate the internal resistance and the open-circuit voltage of the secondary batteries in operation, the secondary batteries being different in manufacturer and type and having various electric characteristics.

(Configuration 2) The learning method of a characteristic estimation model for a secondary battery according to the configuration 1, wherein the current difference is fourth order difference of the time series data on the terminal current, and the voltage difference is fourth order difference of the time series data on the terminal voltage.

According to the learning method of a characteristic estimation model in the configuration 2, the characteristic estimation model makes it possible to more accurately estimate the internal resistance and the open-circuit voltage of the secondary batteries different in manufacturer and type and having various electric characteristics, with use of high order variation aspects of the terminal current Ite and the terminal voltage Vte which can be more common in the secondary batteries different in electric characteristics.

(Configuration 3) The learning method of a characteristic estimation model for a secondary battery according to the configuration 1 or 2, wherein the characteristic estimation model is constituted of a recurrent neural network (RNN).

According to the learning method of a characteristic estimation model in the configuration 3, it is possible to perform effective learning for the characteristic estimation model by efficiently handling the time series data on a plurality of variables.

(Configuration 4) The learning method of a characteristic estimation model for a secondary battery according to the configuration 3, wherein the RNN constituting the characteristic estimation model has an intermediate layer constituted of a long short term memory (LSTM) or a gated recurrent unit (GRU).

According to the learning method of a characteristic estimation model in the configuration 4, it is possible to perform more effective learning for the characteristic estimation model by more efficiently handling the time series data on a plurality of variables.

(Configuration 5) The learning method of a characteristic estimation model for a secondary battery according to the configuration 1 or 2, wherein the characteristic estimation model is constituted of a first order convolutional neural network (CNN).

According to the learning method of a characteristic estimation model in the configuration 5, when, for example, the length of the time series data included in the characteristic estimation input data is configured to be relatively short, accurate estimation results of the internal resistance and the open-circuit can be obtained in shorter processing time.

(Configuration 6) The learning method of a characteristic estimation model for a secondary battery according to the configuration 1 through 5, wherein the characteristic estimation model is generated by learning using time series data on the state variables, including the terminal current and the terminal voltage of each of the plurality of secondary batteries different in electric characteristics, the secondary batteries being connected to a load or a charger.

According to the learning method of a characteristic estimation model in the configuration 6, it is possible to generate the characteristic estimation model capable of accurately estimating the open-circuit voltage of the secondary batteries different in manufacturer and type and having various electruc characteristics

(Configuration 7) A characteristic estimation method for a secondary battery, including: a step of measuring state variables, including terminal current and terminal voltage of the secondary battery in operation, at predetermined time intervals; a step of calculating characteristic estimation input data by preprocessing the state variables; and a step of estimating internal resistance and open-circuit voltage of the secondary battery in operation based on the characteristic estimation input data, using the characteristic estimation model learned by the learning method of a characteristic estimation model for a secondary battery according to any one of the configuration 1 to configuration 6, wherein in the calculating step, current difference that is difference in the terminal current and voltage difference that is difference in the terminal voltage are calculated based on time series data on the terminal current and time series data on the terminal voltage, and the characteristic estimation input data, including time series data on each of the terminal current, the terminal voltage, the current difference and the voltage difference, is generated.

According to the characteristic estimation method in the configuration 7, it is possible to accurately estimate the internal resistance and the open-circuit voltage of the secondary batteries different in manufacturer and type and having various electric characteristics, while the secondary batteries are in operation.

(Configuration 8) A characteristic estimation device for estimating a state of a secondary battery in operation, including: a state observation unit configured to measure state variables, including terminal current and terminal voltage of the secondary battery in operation, at predetermined time intervals; a preprocessing unit configured to calculate input data by preprocessing the state variables measured by the state observation unit; and a state estimation unit configured to estimate a present state of charge and/or a present state of health of the secondary battery in operation based on the input data, wherein the state estimation unit estimates a present internal resistance and a present open-circuit voltage of the secondary battery in operation, using the characteristic estimation model learned by the learning method of a characteristic estimation model for a secondary battery according to any one of the configuration 1 to the configuration 6, and the present state of charge and/or the present state of health of the secondary battery in operation is estimated using the estimated internal resistance and open-circuit voltage.

According to the characteristic estimation device in the configuration 8, it is possible to accurately estimate the internal resistance and the open-circuit voltage of the secondary batteries different in manufacturer and type and having various electric characteristics, while the secondary batteries are in operation, and to accurately estimate the state of charge and/or the state of health of the secondary batteries.

### Reference Signs List

100...MACHINE LEARNING DEVICE, 102, 404...SECONDARY BATTERY, 104...CHARGER, 106 ... LOAD, 108 ... SELECTOR SWITCH, 110, 406 ... CHARACTERISTIC MEASUREMENT DEVICE, 112 ... LEARNING MANAGEMENT DEVICE, 120, 420, 440 ... PROCESSING DEVICE, 122, 428, 448 ... STORAGE DEVICE, 124, 430 ... CHARACTERISTIC ESTIMATION MODEL, 130 ... STATE VARIABLE MEASUREMENT UNIT, 132 ... INPUT DATA GENERATION UNIT, 134...MODEL LEARNING UNIT, 300...INPUT LAYER, 302...INTERMEDIATE LAYER, 304...OUTPUT LAYER, 400...CHARACTERISTIC ESTIMATION DEVICE, 402...VEHICLE, 408 ...ENERGIZATION CONTROLLER, 410 ...ROTARY ELECTRIC MACHINE, 412 ...EXTERNAL CHARGING DEVICE, 414 ...TRAVEL CONTROL DEVICE, 422 ...STATE OBSERVATION UNIT, 424 ...PREPROCESSING UNIT, 426 ...STATE ESTIMATION UNIT, 442 ...MOTOR CONTROL UNIT, 444 ...CHARGE CONTROL UNIT, 446 ...NOTIFICATION CONTROL UNIT, 450 ...DISPLAY DEVICE, 452 ...ACCELERATOR PEDAL SENSOR, 454...BRAKE PEDAL SENSOR, 456...VEHICLE SPEED SENSOR, 500, 502, 504, 506...PROCESS, 600, 602, 604, 606...LINE

What is claimed is:

1. A learning method of a characteristic estimation model for estimating internal resistance and open-circuit voltage of a secondary battery in operation by machine learning, the secondary battery being connected to a load or a charger, the method comprising:
a step of measuring state variables, including terminal current and terminal voltage of the secondary battery in operation, at predetermined time intervals;
a step of calculating characteristic estimation input data by preprocessing the state variables; and
a step of causing the characteristic estimation model to learn relationship of the characteristic estimation input data with the internal resistance and the open-circuit voltage of the secondary battery in operation by machine learning, wherein
in the calculating step,
current difference that is difference in the terminal current and voltage difference that is difference in the terminal voltage are calculated based on time series data on the terminal current and time series data on the terminal voltage, and
the characteristic estimation input data, including time series data on each of the terminal current, the terminal voltage, the current difference and the voltage difference, is generated.

2. The learning method of a characteristic estimation model for a secondary battery according to claim 1, wherein
the current difference is fourth order difference of the time series data on the terminal current, and
the voltage difference is fourth order difference of the time series data on the terminal voltage.

3. The learning method of a characteristic estimation model for a secondary battery according to claim 1, wherein the characteristic estimation model is constituted of a recurrent neural network (RNN).

4. The learning method of a characteristic estimation model for a secondary battery according to claim 3, wherein the RNN constituting the characteristic estimation model has an intermediate layer constituted of a long short term memory (LSTM) or a gated recurrent unit (GRU) .

5. The learning method of a characteristic estimation model for a secondary battery according to claim 1, wherein the characteristic estimation model is constituted of a first order convolutional neural network (CNN) .

6. The learning method of a characteristic estimation model for a secondary battery according to claim 1, wherein the characteristic estimation model is generated by learning using time series data on the state variables including the terminal current and the terminal voltage of each of the plurality of secondary batteries different in electric characteristics, the secondary batteries being connected to a load or a charger.

7. A characteristic estimation method for a secondary battery, comprising:
a step of measuring state variables, including terminal current and terminal voltage of the secondary battery in operation, at predetermined time intervals;
a step of calculating characteristic estimation input data by preprocessing the state variables; and
a step of estimating internal resistance and open-circuit voltage of the secondary battery in operation based on the characteristic estimation input data, using the characteristic estimation model learned by the learning method of a characteristic estimation model for a secondary battery according to claim 1, wherein
in the calculating step,
current difference that is difference in the terminal current and voltage difference that is difference in the terminal voltage are calculated based on time series data on the terminal current and time series data on the terminal voltage, and
the characteristic estimation input data, including time series data on each of the terminal current, the terminal voltage, the current difference and the voltage difference, is generated.

8. A characteristic estimation device for estimating a state of a secondary battery in operation, comprising:
a state observation unit configured to measure state variables, including terminal current and terminal voltage of the secondary battery in operation, at predetermined time intervals;
a preprocessing unit configured to calculate input data by preprocessing the state variables measured by the state observation unit; and
a state estimation unit configured to estimate a present state of charge and/or a present state of health of the secondary battery in operation based on the input data, wherein
the state estimation unit estimates a present internal resistance and a present open-circuit voltage of the secondary battery in operation, using the characteristic estimation model learned by the learning method of a characteristic estimation model for a secondary battery according to claim 1, and
the present state of charge and/or the present state of health of the secondary battery in operation is estimated using the estimated internal resistance and open-circuit voltage.
